(19) United States
(12) Patent Application Publication
(10) Pub. No.: US 2012/0166170 A1
(43) Pub. Date: Jun. 28, 2012

(54) DELAY CIRCUIT, AND DEVICE AND METHOD FOR SIMULATING ASYNCHRONOUS CIRCUIT IN FPGA USING DELAY CIRCUIT

(75) Inventors: Chi-Hoon Shin, Daejeon (KR); Sung-Nam Kim, Daejeon (KR); Myeong-Hoon Oh, Daejeon (KR); Seong-Woon Kim, Gyeryong-si (KR); Jae-Woo Sim, Wonju-si (KR)

(73) Assignee: ELECTRONICS AND TELECOMMUNICATIONS RESEARCH INSTITUTE, Daejeon (KR)

(21) Appl. No.: 13/334,814

(22) Filed: Dec. 22, 2011

(30) Foreign Application Priority Data
Dec. 23, 2010 (KR) 10-2010-0133934

(51) Int. Cl. G06F 17/50; H03L 7/00

(52) U.S. Cl. 703/14; 327/142

(57) ABSTRACT

Disclosed herein is an apparatus for simulating an asynchronous circuit in an FPGA. The apparatus includes a plurality of function execution units, a plurality of delay circuits, and a control unit. The function execution units are set for respective unit functions included in the asynchronous circuit, and are configured to perform the unit functions. The delay circuits are provided for the respective function execution units using a look-up table in the FPGA, and are configured to output delayed input signals by delaying input signals by respective preset delay times. The control unit transmits the input signals to the delay circuits and the function execution units, and receives the delayed input signals from the respective delay circuits.

### CROSS REFERENCE TO RELATED APPLICATION

This application claims the benefit of Korean Patent Application No. 10-2010-0133934, filed on Dec. 23, 2010, which is hereby incorporated by reference in its entirety into this application.

### BACKGROUND OF THE INVENTION

1. Technical Field

The present invention relates generally to a technology for simulating an asynchronous circuit in a synchronous Field Programmable Gate Array (FPGA). More particularly, the present invention relates to a technology for utilizing resources on an FPGA and accurately controlling delay elements in a matched delay environment which requires various delay elements, thereby improving the accuracy of asynchronous circuit simulation.

2. Description of the Related Art

An asynchronous circuit (self-timed circuit) is a generic term for circuits which operate using a method of transmitting data between neighboring modules in conformity with a handshaking protocol without a global clock. An asynchronous circuit is advantageous in terms of the problems generated due to a global clock, that is, a timing closure problem, a power consumption problem generated due to a clock distribution network, a multi clock domain design problem, compared with a synchronous circuit based on a global clock. Recently, research has been carried out into a Globally Asynchronous Locally Synchronous (GALS) structure, which collects the advantages of the above two types of circuits, and performs data transmission between modules in an asynchronous manner based on relatively small-sized synchronous modules which are based on clocks which are different from each other.

Meanwhile, technology has been studied that simulates such an above-described asynchronous circuit on an FPGA which has been used to simulate a plurality of circuits. However, it has been generally known that it is difficult to simulate an asynchronous circuit on an FPGA.

Such an FPGA has been widely used to verify a circuit that has been designed or to flexibly implement a programmable circuit. Here, when FPGA suppliers do not provide the function of deactivating a function of optimizing a circuit, there is the problem in that a delay element which is an essential element for an asynchronous circuit may be removed in the process of optimizing the circuit for the FPGA, and that the delay cannot be accurately controlled because physical elements in the FPGA cannot be consistently composed using a logic circuit level coding method.

Further, although a large amount of delay occurs when interconnection is performed because of the nature of an FPGA, users generally do not control the routing of delays between connections. Therefore, it is more difficult to accurately control a delay circuit implemented on the FPGA.

In order to solve the above-described problems, technologies for separately receiving simulation clocks which function as delay elements from the outside and controlling delays have been proposed. However, since such a technology receives clocks from the outside, there is a problem in that resources are necessarily wasted because a plurality of delay elements in which the unit delay times of respective delay elements are different from each other must be prepared.

Further, when unit delay times are different from each other or functional elements are delayed differently, the restricted number of external clocks which may control the delays is problematic. Therefore, there is a problem in that it is difficult to apply a matched delay method to an asynchronous circuit.

The matched delay method means a method of generating a completion signal using a delay element, which has the margin of safety but is determined to be the worst case, in order to detect the completion of an operation of outputting a result value for a specific input which is supplied to at least one functional unit for performing a specific function of an entire circuit. It is apparent that the number of delays that are necessary varies depending on the number of functional units.

Further, according to the conventional method, signals are applied to a plurality of flip-flops of all the delay modules at the same clock, with the result that a clock skew phenomenon, in which signals reach the flip-flops of the respective delay modules at different times, occurs, so that a separate circuit is required to remove the clock skew phenomenon, thereby generating a problem in that it is difficult to accurately adjust delays because of the nature of an FPGA.

### SUMMARY OF THE INVENTION

An object of the present invention is to provide a technology which is capable of implementing a resourcefully effective delay elements using the resources of an FPGA, capable of effectively supporting a matched delay method with excellent extensity, and capable of accurately controlling the delay elements when implementing the delay elements which are essential to simulate an asynchronous circuit on a synchronous FPGA.

In order to accomplish the above object, the present invention provides a delay circuit for simulating an asynchronous circuit in a Field-Programmable Gate Array (FPGA), including an internal clock generated in the look-up table of the FPGA in order to simulate the asynchronous circuit in the FPGA, and configured to output a pulse signal, having a preset cycle; and a delay control unit configured to transmit a delayed input signal to a control unit after a delay time which is generated using the pulse signal at the request of the control unit.

A plurality of delay circuits, having delay times which are different from each other, may be generated in a look-up table.

The delay control unit may compute the delay time by multiplying the preset cycle of the pulse signal by a delay multiple, and may transmit the delayed input signal after the delay time elapsed.

The delay time may be set so as to correspond to an execution time of a unit function of a function execution unit which executes the unit function.

A plurality of function execution units may be set for the respective functions included in the asynchronous circuit, and a plurality of delay circuits may be generated for the respective function execution units on the look-up table.

The internal clock may include a first input terminal for receiving a reset signal used to control generation of the pulse signal; an output terminal for outputting the pulse signal; and a second input terminal for receiving the pulse signal. Here, the internal clock generates the pulse signal in such a way that a signal received by the second input terminal is toggled and then output by the output terminal.

The delay control unit may include a request input terminal for receiving the request by the control unit; a clock input terminal for receiving the pulse signal; delay multiple input terminals for receiving delay multiples preset to set delay times by multiplying predetermined multiples by the preset cycle; and an output terminal for outputting the delayed input signal.

In order to accomplish the above object, the present invention provides an apparatus for simulating an asynchronous circuit in an FPGA, including a plurality of function execution units which are set for respective execution functions included in the asynchronous circuit, and which are configured to perform the execution functions; a plurality of delay circuits each of which is set in a look-up table in the FPGA, generated for each of the function execution units, and configured to output a delayed input signal after a delay time corresponding to the execution time of the relevant execution function elapsed; and a control unit which is configured to transmit an input signal, which notifies the start of the execution function and requests the transmission of the delayed input signal, to each of the delay circuits and each of the function execution units, and to transmit the input signal to another function execution unit and another delay circuit when the delayed input signal is received.

The function execution units may have execution times which are different from each other depending on the unit functions.

The delay circuit may compute the delay time by multiplying the preset cycle of the pulse signal, which is set in the delay circuit, by a delay multiple, which is preset for each function execution unit, and may output the delayed input signal after the input signal was received and then the computed delay time elapsed.

The control unit may transmit the input signal to the function execution unit and the delay circuit in an order in which the unit functions are executed.

In order to accomplish the above object, the present invention provides a method of simulating an asynchronous circuit in an FPGA, including allocating memory of a look-up table in the FPGA to each execution function included in the asynchronous circuit used for simulation using a control unit; setting execution time of the input execution function using the control unit; when the execution function starts, generating a delay circuit, which outputs a delayed input signal after a delay time corresponding to the set execution time elapsed, in the allocated memory of the look-up table; and simulating the asynchronous circuit in the FPGA.

The method may further comprising modifying the look-up table corresponding to a delay circuit to be modified when the control unit modifies the execution order of the execution function and a delay time corresponding to the execution function.

The generating may include generating an internal clock for outputting the pulse signal having a predetermined cycle in the look-up table, and may further include generating a delay control unit for receiving the pulse signal, and computing the delay time by multiplying the preset cycle by a delay multiple which is preset according to the delay time.

The simulating may include transmitting the input signal, used to notify the start of the execution function and to request to transmit the delayed input signal, to the function execution unit which is set for each execution function and a delay circuit which corresponds to the function execution unit, using the control unit; outputting the delayed input signal using the delay circuit after the set delayed time elapsed; and receiving the delayed input signal using the control unit.

The simulating may be repeated until all the execution functions included in the asynchronous circuit are performed. Further, the simulating may further include, when the control unit receives the delayed input signal, transmitting the input signal to another function execution unit and another delay circuit corresponding to the another function execution unit.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram illustrating a circuit for simulating an asynchronous circuit in an FPGA according to an embodiment of the present invention;

FIG. 2 is a block diagram illustrating a device for simulating an asynchronous circuit in an FPGA according to another embodiment of the present invention;

FIG. 3 is a view illustrating an example in which detailed terminals of each of the configurations of a delay circuit are implemented;

FIG. 4 is a view illustrating an example of the waveforms of respective signals based on the operation of the delay circuit;

FIG. 5 is a view illustrating an example in which detailed terminals of the device for simulating an asynchronous circuit are implemented;

FIG. 6 is a view illustrating an example of an operation when an internal clock is implemented in a look-up table;

FIG. 7 is a flowchart illustrating a method of simulating an asynchronous circuit in an FPGA according to an embodiment of the present invention; and

FIG. 8 is a flowchart illustrating the flow of the operation of the delay circuit in the process of simulating an asynchronous circuit.

### DESCRIPTION OF THE PREFERRED EMBODIMENTS

An apparatus, delay circuit, and method for simulating an asynchronous circuit in an FPGA according to an embodiment of the present invention will be described below with reference to the accompanying drawings. It will be understood that the same reference numerals indicate the same configurations in the description below.

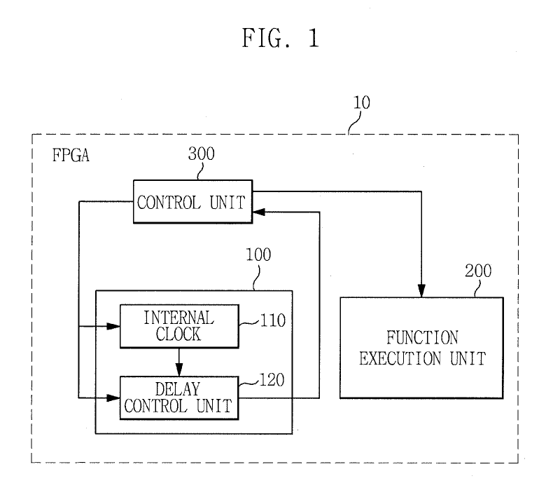

FIG. 1 is a block diagram illustrating a circuit for simulating an asynchronous circuit in an FPGA according to an embodiment of the present invention.

Referring to FIG. 1, a delay circuit 100 for simulating an asynchronous circuit on an FPGA 10 according to the embodiment of the present invention includes an internal clock 110 and a delay control unit 120.

In the present invention, the delay circuit 100 is generated using a look-up table (not shown) provided in the FPGA 10. The FPGA 10 according to the present invention is a universal type look-up table-based FPGA 10. A look-up table is the basic element in the form of the memory of the FPGA 10, and means memory table-type hardware which implements all types of functional circuits, each having one-bit output and n-bit input. Such a look-up table includes 2ⁿ storage capacity based on the number of inputs.

Each storage capacity stores output information based on inputs. Therefore, if the number of inputs of the look-up table is 2, the number of the pieces of output information depending on the input is 4. When each of the inputs is matched with the output information, all types of logic circuits, each having 2 inputs and 1 output, may be implemented.

In the look-up table-based FPGA 10, such a look-up table functions as a general core and basic circuit implementation element, and, at the same time, the purpose thereof may be converted into purposes that are for various other uses, such as Random Access Memory (RAM), Read Only Memory (ROM), and a shift counter, as well as the basic function of the look-up table 20, depending on the situation.

Therefore, in the present invention, a delay control element using the functions of a clock supplied to delay elements and a shift counter is formed using the look-up table based on the properties of the look-up table. Generally, hardware designers who use the FPGA 10 do not directly control a look-up table which is the basic physical element of the FPGA 10. However, all the enterprises which supply most of the current look-up table-based FPGAs 10 permit a look-up table to be directly controlled. Therefore, the FPGA 10 may be accurately controlled using the direct control, thereby controlling delays. The purpose of the present invention is to implement the delay circuit 100 using the above-described look-up table.

The internal clock 110 is included in the delay circuit 100 generated using a look-up table according to the embodiment of the present invention, and configured to perform a function of performing self-oscillation without receiving a clock from the outside and providing a pulse signal having a preset cycle.

For example, it is assumed that the number of inputs of the internal clock 110 is 2, the number of outputs is 1, one of the inputs is determined to be a reset signal, and the remaining one input becomes the output. Thereafter, setting is made such that the value of the output is output as the following table.

TABLE 1

| Reset Signal | Input Signal | Output Signal |
|---|---|---|
| 0 | 0 | 0 |
| 0 | 1 | 0 |
| 1 | 0 | 1 |
| 1 | 1 | 0 |

Referring to Table 1, when the reset signal is 1, the pattern of 1-0-1-0-1-0-1-0 is infinitely repeated. Therefore, the internal clock 110 generates a pulse signal having a cycle corresponding to a time that 1-0 are output. The generated pulse signal is output in such a way that one of the input bits is continuously toggled, so that the pulse signal becomes a signal which varies within a preset cycle.

The delay control unit 120 performs the function of transmitting a delayed input signal to the control unit 300 after a delay time generated using the pulse signal has elapsed at the request of the control unit 300.

That is, the delay control unit 120 performs the function of performing separate logic that is used to control the degree of delay. In the present invention, the delay control unit 120 means a shift counter which may be implemented using a look-up table, and the degree of shift is defined using delay multiples.

Generally, FPGA 10 suppliers provide a method capable of effectively implementing a shift counter, so that the delay control unit 120 can be implemented using a look-up table. In the present invention, a delay multiple, that is, the degree of delay may be implemented up to a delay time corresponding to a predetermined multiple based on the cycle of the pulse signal generated by the internal clock 110. Delay multiples and input values A0, A1, A2, and A3, which are used to set the delay multiples, are as follows.

TABLE 2

| A0 | A1 | A2 | A3 | Delay Multiple |
|---|---|---|---|---|
| 0 | 0 | 0 | 0 | 1x |
| 0 | 0 | 0 | 1 | 2x |
| 0 | 0 | 1 | 0 | 3x |
| 0 | 0 | 1 | 1 | 4x |
| 0 | 1 | 0 | 0 | 5x |
| 0 | 1 | 0 | 1 | 6x |
| 0 | 1 | 1 | 0 | 7x |
| 0 | 1 | 1 | 1 | 8x |
| 1 | 0 | 0 | 0 | 9x |
| 1 | 0 | 0 | 1 | 10x |
| 1 | 0 | 1 | 0 | 11x |
| 1 | 0 | 1 | 1 | 12x |
| 1 | 1 | 0 | 0 | 13x |
| 1 | 1 | 0 | 1 | 14x |
| 1 | 1 | 1 | 0 | 15x |
| 1 | 1 | 1 | 1 | 16x |

Referring to Table 2, it can be seen that the delay multiple is set to maximum of 16 times in the embodiment of the present invention. The reason for this is that the input bit of the delay multiple is 4. However, other embodiments of the present invention are not limited thereto.

A delay multiple may be previously set based on an execution time required to execute a function, and may be received from the outside. A delay multiple may be easily modified by accessing a look-up table. Therefore, when an execution time varies depending on the type and execution function of the FPGA 10 device, a delay time may be easily varied by adjusting a delay multiple.

When the delay control unit 120 receives a pulse signal from the internal clock 110, the delay control unit 120 computes a delay time by extracting the preset cycle of the pulse signal, and multiplying a delay multiple that has been preset for each execution function. Therefore, a delayed input signal notifying the completion of a function may be transmitted after the corresponding delay time has elapsed since the start of the corresponding function.

Therefore, the delay time may be a time corresponding to an execution time that is required for the function execution unit 200 to execute a specific function. Preferably, as described above, the delay time may be set to the execution time of the worst case from among function execution times. Therefore, the delay of an asynchronous circuit may be stably controlled.

There may be a plurality of delay circuits 100 depending on the degree of resources of a look-up table included in the FPGA 10 according to the embodiment of the present invention. That is, in order to effectively control delays which may be generated when a plurality of functions, having respective delay times which are different from each other, are executed, the plurality of delay circuits 100, in which setting is made such that the delay times thereof are different from each other, is generated.

The fact that setting is made such that delay times are different from each other means that setting is made such that the cycles or delay multiples of respective pulse signals are different from each other.

Therefore, there may be a plurality of function execution units 200 for respective unit functions included in the asynchronous circuit. Since the execution times of the function execution units 200 are different from each other and the function execution units 200 perform unit functions which are different from each other, a plurality of delay circuits 100 should also be generated.

Here, each of the delay circuits 100 is generated so as to correspond to each of the function execution units 200. The reason for this is that, even when there are function execution units 200 which have the same delay time, it may be difficult to accurately control delays if a clock skew phenomenon occurs as described in the description of the related art.

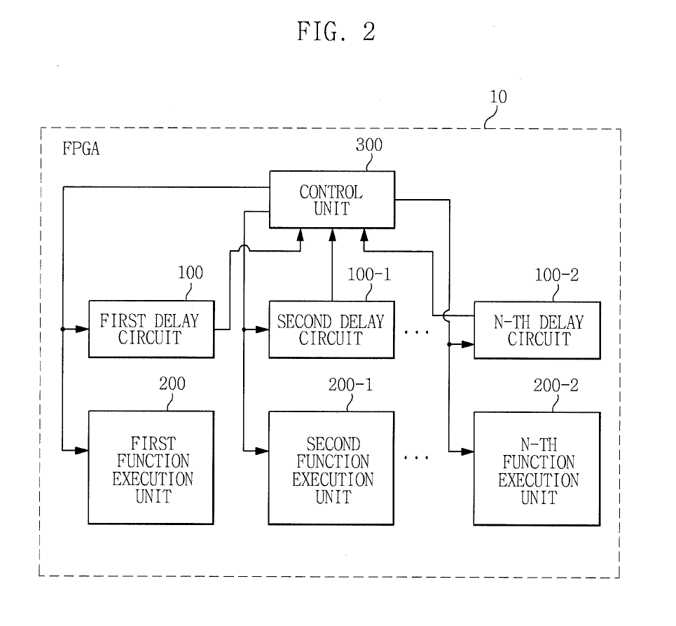

FIG. 2 is a block diagram illustrating a device for simulating an asynchronous circuit in an FPGA according to another embodiment of the present invention. The portions which are duplicated with those in the description of FIG. 1 will be omitted below.

Referring to FIG. 2, the device for simulating an asynchronous circuit in the FPGA 10 according to the embodiment of the present invention includes a control unit 300, a function execution unit 200, and a delay circuit 100. As described above, there may be a plurality of function execution units 200, 200-1, and 200-2 based on a plurality of unit functions included in an asynchronous circuit to be simulated. Further, there may be a plurality of delay circuits 100, 100-1, and 100-2 corresponding to the plurality of function execution units 200, 200-1, and 200-2, respectively. That is, the pairs of the delay circuit 100 and the function execution unit 200 may exist.

If there are N pairs of the delay circuit 100 and the function execution unit 200, the control unit 300 may include 2N input terminals. The reason for this is that the control unit 300 should transmit an input signal used to request a delayed input signal from the delay circuit 100 and to request that a unit function perform from the function execution unit 200, and should receive a delayed input signal from the delay circuit 100.

The delay circuits 100, 100-1, and 100-2 may include respective delay times which are different from each other. That is, when the respective delay circuits 100, 100-1, and 100-2 receive input signals, the respective delay circuits 100, 100-1, and 100-2 output delayed input signals after times which are different from each other elapse. The delay times for the respective delay circuits 100, 100-1, and 100-2 may correspond to execution times that the relevant function execution units 200, 200-1, and 200-2 execute the functions thereof.

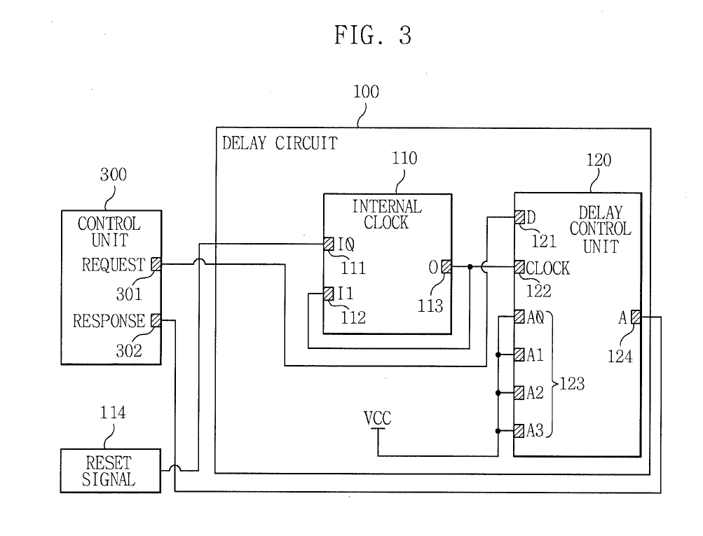

FIG. 3 is a view illustrating an example in which detailed terminals of each of the configurations of a delay circuit are implemented. The portions which are duplicated with those in the description of FIGS. 1 and 2 will be omitted below.

Referring to FIG. 3, the control unit 300 includes an input signal transmission terminal 301 for transmitting an input signal, used to notify the delay control unit 120 of the start of the execution of a function and to request a delayed input signal from the delay control unit 120, and a delayed input signal reception terminal 302 for receiving the delayed input signal output from the delay control unit 120.

The internal clock 110 includes a first input terminal 111 for receiving a reset signal 114, a second input terminal 112 for receiving a pulse signal which is an output signal, and an output terminal 113 for outputting the pulse signal.

The delay control unit 120 includes a delay input terminal 121 configured to receive an input signal related to the request of the delayed input signal from the control unit 301, a clock input terminal 122 connected to the output terminal 113 in order to receive the pulse signal from the internal clock 110, delay multiple input terminals 123 configured to receive values preset for respective delay multiples, and a delay output terminal 124 configured to output the delayed input signal.

First, the input signal transmission terminal 301 transmits an input signal to the delay input terminal 121 in order to notify the start of the execution of a function of the function execution unit 200, and, at the same time, request a delayed input signal which indicates the completion of the execution of the function.

Here, the internal clock 110 may generate a pulse signal which is output while the signal thereof is continuously toggled in such a way that the second input terminal 112 receives a signal generated at the output terminal 113 when the reset signal 114 is 1 (or may be 0) and that a subsequent output value is determined to be a value obtained by toggling the current output value which is input to the second input terminal 112.

The clock input terminal 122 receives the pulse signal, the pulse signal is repeated for a predetermined cycle from the time point at which the input signal was received based on the delay multiples set in the delay multiple input terminals 123, and then the delayed input signal is output through the output terminal 124. The delayed input signal is received by the delayed input signal reception terminal 302 of the control unit 300 from the output terminal 124.

Therefore, the control unit 300 may receive the delayed input signal from the delay circuit 100 based on an accurately controlled delay time. Subsequently, the control unit 300 may transmit an input signal again to a delay circuit corresponding to a function execution unit which will perform a subsequent function, and the process may be repeated until all the functions of the asynchronous circuit are completed.

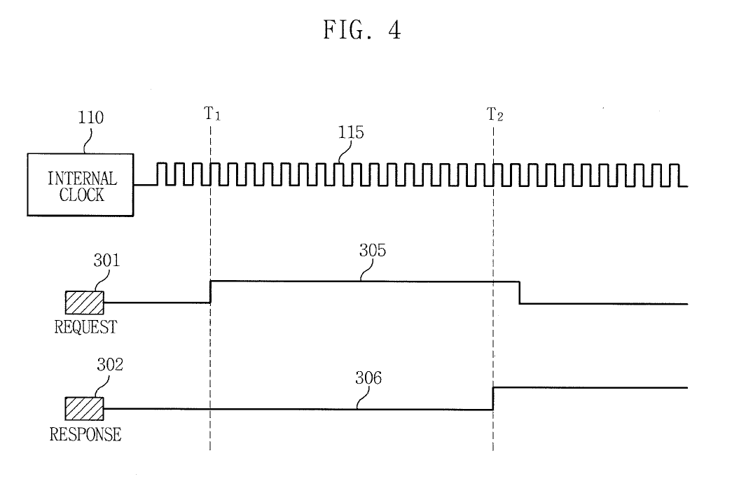

FIG. 4 is a view illustrating an example of the waveforms of respective signals based on the operation of the delay circuit.

Referring to FIG. 4, the internal clock 110 continuously toggles an output bit and then subsequently outputs the resulting bit, thereby outputting a pulse signal 115 having a predetermined cycle. The predetermined cycle of the pulse signal 115 will be used as the units of a delay time in the present invention.

When an input signal 305 is output from the input signal transmission terminal 301, the delay input terminal 121 receives the input signal 305. A delay time is calculated on the basis of a time T1 that the input signal 305 is received. It is assumed that a time, required to transmit a signal between the input signal transmission terminal 301 and the delay input terminal 121, does not exist in the present invention. However, preferably, the input signal reception time T1, which is the reference of the output of the delayed input signal, may be the time when the delay input terminal 121 receives the input signal 305. The input signal 305 may be a pulse signal which continues for a predetermined time.

It is assumed that a delay multiple is set to 16× in the embodiment of FIG. 4. Therefore, the delay control unit 120 delays the output of a delayed input signal until the cycle of the pulse signal is repeated 16 times from the input signal reception time T1. Thereafter, the delayed input signal reception terminal 302 receives the delayed input signal 306 at a time T2 that the cycle of the pulse signal has been repeated 16 times from the time T1, or the delayed input signal 306 is output from the output terminal 124. As described above, it is assumed that a time, required to transmit a signal between the delayed input signal reception terminal 302 and the delay output terminal 124, does not exist.

When a delay time (T2-T1) varies, the delay time may be differently adjusted by differently setting a delay multiple using a simple operation of changing bits which are input to the delay multiple input terminals 123.

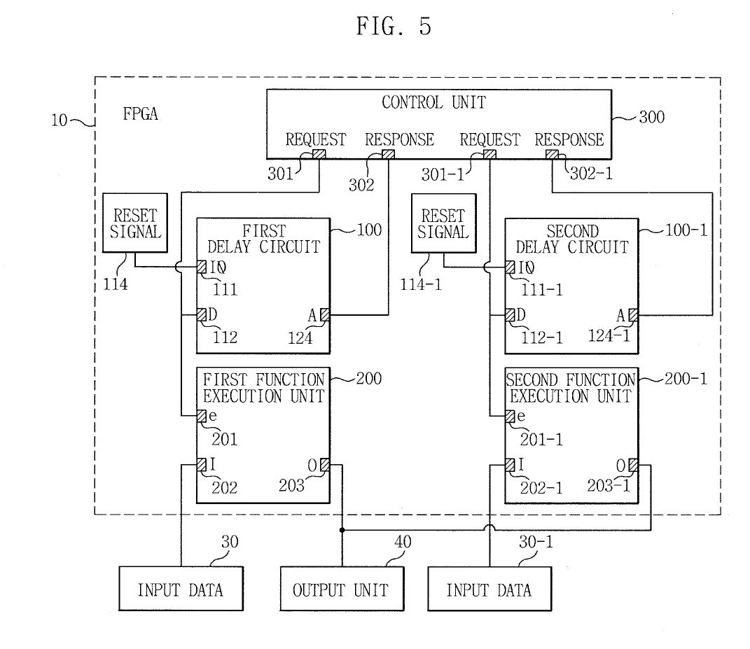

FIG. 5 is a view illustrating an example in which detailed terminals of the device for simulating an asynchronous circuit are implemented. The portions which are duplicated with those in the description of FIGS. 1 and 2 will be omitted below.

Referring to FIG. 5, the control unit 300 includes input signal transmission terminals 301 and 301-1 and delayed input signal reception terminals 302 and 302-1. In the embodiment of FIG. 5, two function execution units 200 and 200-1 exist, so that two terminals 301 and 301-1 and two terminals 302 and 302-1 exist.

The first input terminals 111 and 111-1 of respective delay circuits 100 and 100-1 are connected to respective reset signals 114 and 114-1, and delay input terminals 112 and 112-1 are connected to the respective input signal transmission terminals 301 and 301-1. The delay output terminals 124 and 124-1 are connected to the respective delayed input signal reception terminals 302 and 302-1 of the control unit 300.

The function execution units 200 and 200-1 respectively include function execution input terminals 201 and 201-1 which are connected to the respective input signal transmission terminals 301 and 301-1. When the function execution input terminals 201 and 201-1 receive input signals, the function execution units 200 and 200-1 will start their unique functions.

Further, the function execution units 200 and 200-1 respectively include data input terminals 202 and 202-1 for receiving input data 30 and 30-1 in order to execute their unique functions, and data output terminals 203 and 203-1 for outputting the function execution results of the function execution units 200 and 200-1 to an output unit 40.

That is, the asynchronous circuit can be simulated in such a way that delay is accurately controlled by connecting and simply controlling each of the terminals in the FPGA 10 using the above-described configuration.

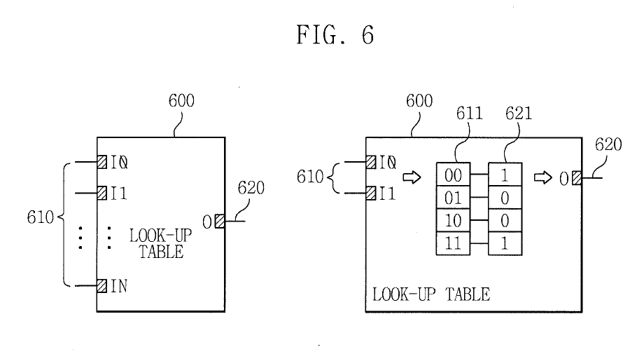

FIG. 6 is a view illustrating an example of an operation when an internal clock is implemented in a look-up table.

Referring to FIG. 6, the internal clock 110 is implemented within the look-up table 600. As described above, the look-up table 600 is the basic configuration of the FPGA 10, which can perform almost all of the functions of receiving a plurality of inputs and then generating a single output.

Therefore, the look-up table 600 may include a plurality of input terminals 610, having I0 to IN, and a single output terminal 620.

FIG. 6 illustrates an example in which two input terminals 610, having I0 and I1, and a single output terminal 620 are implemented. The look-up table 600 stores data 611 corresponding to input values based on the input to the input terminal 610, and data 621 corresponding to an output value based on the input values. Therefore, various functions can be implemented based on a method of matching the data 611 and 621.

FIG. 6 is an implementation of a logic circuit in which an output value is 1 when the same values are input through the two input terminals I0 and I1, otherwise, the output value is 0. However, in order to implement the internal clock 110 using the look-up table 600, setting is made such that, when the input value input through the first input terminal I0 is 0, the output value is 0, setting is made such that, when the input value input through the input terminal I0 is 1, the output value is 1 if the value input through the second input terminal I1 is 0, and the output value is 0 if the value input through the second input terminal I1 is 1, and the output terminal 620 is connected to the second input terminal I1, thereby simply implanting the internal clock 110.

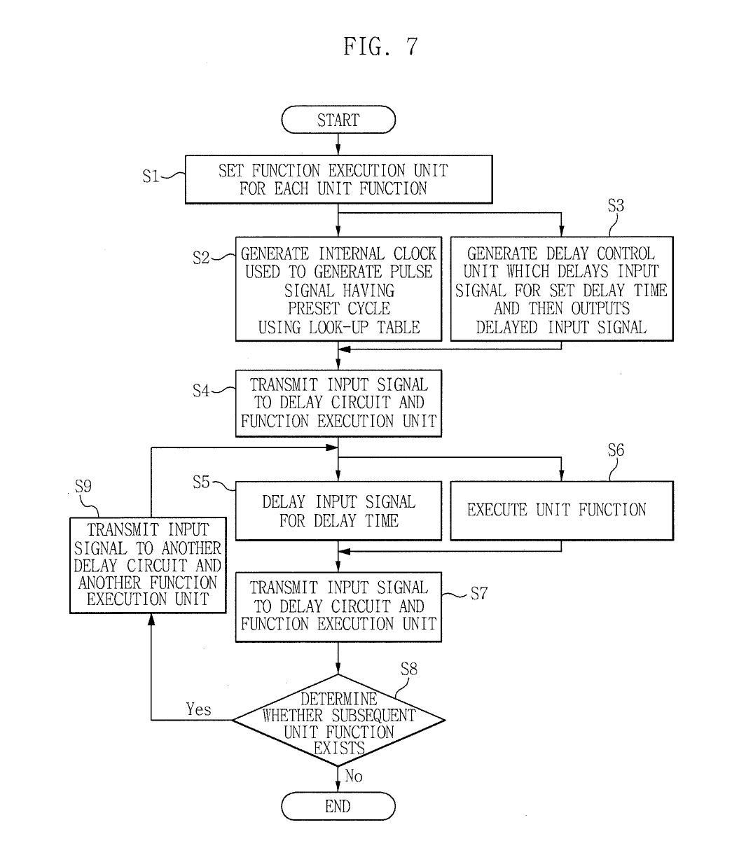

FIG. 7 is a flowchart illustrating a method of simulating an asynchronous circuit in an FPGA according to an embodiment of the present invention.

Referring to FIG. 7, in the method of simulating an asynchronous circuit in an FPGA according to the embodiment of the present invention, the function of the asynchronous circuit is divided into unit functions, and then function execution units 200 corresponding to the resulting unit functions are set at step S1.

Thereafter, the internal clock 110 and the delay control unit 120 are generated using a look-up table at steps S2 and S3. The internal clock 110 is used to generate a pulse signal having preset cycle. The delay control unit 120 is used to delay an input signal for a set delay time, and then outputs a delayed input signal.

When the internal clock 110 and the delay control unit 120 are generated so as to correspond to each of the function execution units 200, the control unit 300 transmits the input signal to the delay circuit 100 and the function execution unit 200 at step S4. The input signal is used the cause the delay circuit 100 to transmit the delayed input signal, and configured to function as a command signal which is transmitted to the function execution unit 200 in order to perform control such that the function execution unit 200 starts the corresponding unit function.

When the function execution unit 200 receives the input signal, the function execution unit 200 starts the unit function thereof at step S6. At the same time, the delay circuit 100 delays the input signal for a preset delay time at step S5.

When the input signal is delayed for the preset delay time, the delayed input signal is transmitted to the control unit 300 by the delay circuit 100 at step S7.

When the control unit 300 receives the input signal, the control unit 300 determines that the unit function of the function execution unit 200 is completed. Thereafter, the control unit 300 controls the execution of another unit function. That is, when the control unit 300 receives the input signal, the control unit 300 determines whether a subsequent unit function exists based on the order of execution of unit functions of the asynchronous circuit at step S8.

If a subsequent unit function exists, the control unit 300 transmits an input signal to another delay circuit and another function execution unit which correspond to the subsequent unit function, like step S4, again, at step S9. Therefore, steps S5 to S7 are repeated. Such a series of sequences are repeated until all the simulations for the asynchronous circuit are completed.

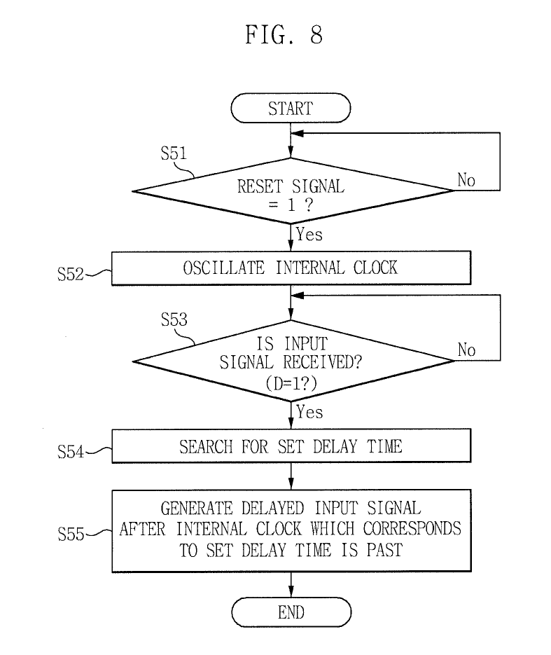

FIG. 8 is a flowchart illustrating the flow of the operation of the delay circuit in the process of simulating the asynchronous circuit. That is, FIG. 8 is a flowchart illustrating the process of transmitting the delayed input signal using the delay circuit 100 at step S4 of FIG. 7 in detail.

Referring to FIG. 8, first, it is determined whether a reset signal is set to 1, that is, a pulse signal is generated by the internal clock 110 at step S51. If the reset signal is set to 1 such that a pulse signal is generated by the internal clock 110, an internal clock is oscillated at step S52, so that a pulse signal is generated.

One of a plurality of delay circuits 100 receives a delay request according to priority. Therefore, the request input terminal 121 of the delay control unit 120 of the delay circuit 100 detects whether an input signal exists at step S53. When the input signal is 1 and the existence of the input signal is detected, a delay time corresponding to a delay multiple, input to the delay multiple input terminal 123, is searched for at step S54.

Thereafter, after waiting for a pulse signal for the delay time, that is, after the pulse signal of the internal clock 110, which corresponds to the set delay time, is past, a delayed input signal is generated at step S55. That is, as shown in FIG. 4, the delayed input signal 306 is changed to 1. Therefore, the delay is accurately controlled, so that the asynchronous circuit may be simulated.

According to the above-described present invention, a delay circuit may be implemented using a look-up table which generally exists in an FPGA. Since the look-up table is used as a clock, delay can be accurately controlled, and a variety and large number of delay elements may be provided in the range of the resources (or memory) of the look-up table of the FPGA, thereby increasing extendibility. Further, the minimum of two elements, that is, the internal clock and delay control unit of the look-up table are required to implement a delay element, thereby being economic.

Further, even when the configurations of an asynchronous circuit, which will be simulated, that is, the functions are varied, modification can be performed by simply adjusting the internal clock and the delay control unit of the look-up table. Since the modification is performed in the same manner when an FPGA device is changed, there is the advantage of high adaptability for an asynchronous circuit and an FPGA device.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A delay circuit for simulating an asynchronous circuit in a Field-Programmable Gate Array (FPGA), comprising:
an internal clock for generating a pulse signal, having a preset cycle, using a look-up table in which setting is made such that an output signal is changed based on the preset cycle; and
a delay control unit for outputting a delayed input signal by delaying an input signal for a delay time which is set using the pulse signal, wherein the delay control unit is configured to use the look up table.

2. The delay circuit as set forth in claim 1, wherein the internal clock is set such that one of input bits of the look-up table is toggled and then output.

3. The delay circuit as set forth in claim 2, wherein the internal clock comprises:
a first input terminal for receiving a reset signal used to control generation of the pulse signal;
an output terminal for outputting the pulse signal; and
a second input terminal for receiving the pulse signal.

4. The delay circuit as set forth in claim 1, wherein the delay control unit computes the delay time by multiplying the preset cycle by a delay multiple.

5. The delay circuit as set forth in claim 1, wherein the delay time is set so as to correspond to an execution time of a unit function of a function execution unit which executes the unit function.

6. The delay circuit as set forth in claim 1, wherein the delay control unit comprises:
a delay input terminal for receiving the input signal related to a request of a delayed input signal;
a clock input terminal for receiving the pulse signal;
delay multiple input terminals for receiving delay multiples to be multiplied by the preset cycle; and
a delay output terminal for outputting the delayed input signal.

7. An apparatus for simulating an asynchronous circuit in an FPGA, comprising:
a plurality of function execution units which are set for respective unit functions included in the asynchronous circuit, and which are configured to perform the unit functions;
a plurality of delay circuits which are provided for the respective function execution units using a look-up table in the FPGA, and which are configured to output delayed input signals by delaying input signals by respective preset delay times; and
a control unit which is configured to transmit the input signals to the delay circuits and the function execution units, and to receive the delayed input signals from the respective delay circuits.

8. The apparatus as set forth in claim 7, wherein each of the delay circuits computes the delay time using a pulse signal having a preset cycle based on the look-up table in which setting is made such that an output signal varies according to the preset cycle.

9. The apparatus as set forth in claim 8, wherein the delay circuit is set such that one of input bits of the look-up table is toggled and then output.

10. The apparatus as set forth in claim 8, wherein the delay circuit computes the delay time by multiplying the preset cycle by a delay multiple.

11. The apparatus as set forth in claim 7, wherein delay time is set so as to correspond to an execution time of a unit function.

12. The apparatus as set forth in claim 7, wherein each of the function execution units has a different execution time.

13. The apparatus as set forth in claim 7, wherein the control unit transmits the input signal to another delay circuit and another function execution unit, when the control unit receives the delayed input signal.

14. The apparatus as set forth in claim 7, wherein the function execution unit performs the unit function, when each of the function execution units receives the input signal.

15. The apparatus as set forth in claim 9, wherein the control unit transmits the input signal to the function execution unit and the delay circuit in an order in which the unit functions are executed.

16. A method of simulating an asynchronous circuit on an FPGA, comprising:
transmitting an input signal to one of a plurality of delay circuits and one of a plurality of function execution units using a control unit;
executing a corresponding unit function when one of the function execution units, which are included in the asynchronous circuit and are set for respective unit functions, receives the input signal;
outputting a delayed input signal in such a way that one of the delay circuits, which are generated for the respective function execution units using a look-up table in the FPGA, delays the input signal for a preset delay time; and
receiving the delayed input signal from the delay circuit using the control unit.

17. The method as set forth in claim 16, wherein the outputting comprises computing the delay time using a pulse signal having a preset cycle based on the look-up table in which setting is made such that an output signal varies according to the preset cycle.

18. The method as set forth in claim 17, wherein the outputting comprises generating the pulse signal in such a way that one of input bits of the look-up table is toggled and then output.

19. The method as set forth in claim 17, wherein the outputting comprises computing the delay time by multiplying the preset cycle by a delay multiple.

20. The method as set forth in claim 16, further comprising, after the receiving is performed, transmitting the input signal to another delay circuit and another function execution unit using the control unit in an order in which the unit functions are executed.
